(19) United States
(12) Patent Application Publication
(10) Pub. No.: US 2026/0062787 A1
(43) Pub. Date: Mar. 5, 2026

(54) METHOD FOR MANUFACTURING MASK

(71) Applicant: Samsung Display Co., LTD., Yongin-si (KR)

(72) Inventors: Jeong Kuk KIM, Yongin-si (KR); Dong Gyun KIM, Yongin-si (KR); Young Jin SONG, Yongin-si (KR); Ji Hyun JUNG, Yongin-si (KR); Jun Ho JO, Yongin-si (KR)

(21) Appl. No.: 19/069,014

(22) Filed: Mar. 3, 2025

(30) Foreign Application Priority Data
Sep. 4, 2024 (KR) 10-2024-0120249

(51) Int. Cl. C23C 14/04; H10K 71/16

(52) U.S. Cl. CPC C23C 14/042; H10K 71/166

(57) ABSTRACT

A method for manufacturing a mask that utilizes a laminate is disclosed. The laminate may include: a silicon substrate; a first lower inorganic layer that covers the lower surface of the silicon substrate; a second lower inorganic layer that covers a lower surface of the first lower inorganic layer; a first upper inorganic layer that covers an upper surface of the silicon substrate; and a second upper inorganic layer that covers an upper surface of the first upper inorganic layer. The method may include: forming or providing first openings; forming or providing a first pattern portion and second pattern portions; forming or providing a second opening that overlaps the first openings by etching the silicon substrate through the first pattern portion and the second pattern portions; and removing the first lower inorganic layer, the second lower inorganic layer, and the first upper inorganic layer that overlap the second opening.

### CROSS-REFERENCE TO RELATED APPLICATION

The present application claims priority to and the benefit of Korean Patent Application No. 10-2024-0120249, filed on Sep. 4, 2024, the entire disclosure of which is incorporated herein by reference.

### BACKGROUND

### 1. Field

One or more embodiments of the present disclosure relate to a method for manufacturing a mask.

### 2. Description of the Related Art

A display device is a device having an organic light emitting element in a display area, and the organic light emitting element includes a pixel electrode and a common electrode that face each other, and an organic light emitting material between the pixel electrode and the common electrode. The display device may be applied to one or more suitable electronic devices.

If (e.g., when) the display device (or electronic device) is manufactured, one or more suitable methods may be used to form or provide the organic light emitting material. For example, a deposition process that utilizes a mask may be used.

### SUMMARY

One or more aspects of embodiments of the present disclosure are directed toward a method for manufacturing a mask having improved or enhanced reliability.

Additional aspects of embodiments will be set forth in part in the description which follows and, in part, will be apparent from the description or may be learned by practice of the presented embodiments of the disclosure.

A method for manufacturing a mask that utilizes a laminate according to one or more embodiments of the present disclosure, wherein the laminate may include a silicon substrate having a single crystal whose lower surface is a (100) plane, a first lower inorganic layer that covers the lower surface of the silicon substrate, a second lower inorganic layer that covers a lower surface of the first lower inorganic layer, a first upper inorganic layer that covers an upper surface of the silicon substrate, and a second upper inorganic layer that covers an upper surface of the first upper inorganic layer, may include: forming or providing first openings that penetrate the second upper inorganic layer within a cell opening area and expose the upper surface of the first upper inorganic layer; forming or providing a first pattern portion and second pattern portions within the cell opening area, wherein the first pattern portion penetrates the first lower inorganic layer and the second lower inorganic layer and exposes the lower surface of the silicon substrate, and wherein the second pattern portions are surrounded by the first pattern portion if (e.g., when) viewed on a plane; forming or providing a second opening that overlaps the first opening by etching the silicon substrate through the first pattern portion and the second pattern portions; and removing the first lower inorganic layer, the second lower inorganic layer, and the first upper inorganic layer that overlap the second opening. Each of sides that constitutes the first pattern portion may be parallel (e.g., substantially parallel) to a [010] direction or a [001] direction if (e.g., when) viewed on a plane, and each of sides that constitutes the second pattern portions may be parallel (e.g., substantially parallel) to a [011] direction or a [011] direction if (e.g., when) viewed on a plane.

According to one or more embodiments, the first pattern portion may include an outer edge and an inner edge if (e.g., when) viewed on a plane, and each of the outer edge and the inner edge may have a rectangular shape (e.g., a substantially rectangular shape).

According to one or more embodiments, the second pattern portions may be surrounded by the inner edge of the first pattern portion if (e.g., when) viewed on a plane.

According to one or more embodiments, the second pattern portions may include a (2-1)th pattern portion in which a length of one side is equal (e.g., substantially equal) to a length of an adjacent other side if (e.g., when) viewed on a plane.

According to one or more embodiments, the second pattern portions may include a (2-2)th pattern portion in which a length of one side is different from a length of an adjacent other side if (e.g., when) viewed on a plane.

According to one or more embodiments, among the second pattern portions, an area of each of one or more of the second pattern portions on a plane may be different from an area of each of one or more of the remaining second pattern portions on a plane.

According to one or more embodiments, the first lower inorganic layer and the first upper inorganic layer may include a first inorganic insulating (e.g., electrically insulating) material, and the second lower inorganic layer and the second upper inorganic layer may include a second inorganic insulating (e.g., electrically insulating) material.

According to one or more embodiments, the first inorganic insulating (e.g., electrically insulating) material may be silicon oxide, and the second inorganic insulating (e.g., electrically insulating) material may be silicon nitride.

According to one or more embodiments, in the forming or providing the second opening, the silicon substrate may be etched by wet etching.

According to one or more embodiments, the mask may be a deposition mask that is utilized to selectively deposit an organic material on a display substrate.

A method for manufacturing a mask that utilizes a laminate according to one or more embodiments of the present disclosure, wherein the laminate may a silicon substrate having a single crystal whose lower surface is a (100) plane, a first lower inorganic layer that covers the lower surface of the silicon substrate, a second lower inorganic layer that covers a lower surface of the first lower inorganic layer, a first upper inorganic layer that covers an upper surface of the silicon substrate, and a second upper inorganic layer that covers an upper surface of the first upper inorganic layer, may include: forming or providing first openings that penetrate the second upper inorganic layer within a cell opening area and expose the upper surface of the first upper inorganic layer; forming or providing a first pattern portion and second pattern portions within the cell opening area, wherein the first pattern portion penetrates the first lower inorganic layer and the second lower inorganic layer and exposes the lower surface of the silicon substrate, and wherein the second pattern portions are surrounded by the first pattern portion if (e.g., when) viewed on a plane; removing the second lower inorganic layer that overlaps an area surrounded by the first pattern portion if (e.g., when) viewed on a plane; forming or providing a second opening that overlaps the first opening by etching the silicon substrate through the first pattern portion and the second pattern portions; and removing the first lower inorganic layer and the first upper inorganic layer that overlap the second opening. Each of sides that constitutes the first pattern portion may be parallel (e.g., substantially parallel) to a [010] direction or a [001] direction if (e.g., when) viewed on a plane, and each of sides that constitutes the second pattern portions may be parallel (e.g., substantially parallel) to a [011] direction or a [011] direction if (e.g., when) viewed on a plane.

According to one or more embodiments, the first pattern portion may include an outer edge and an inner edge if (e.g., when) viewed on a plane, and each of the outer edge and the inner edge may have a rectangular shape (e.g., a substantially rectangular shape).

According to one or more embodiments, the second pattern portions may be surrounded by the inner edge of the first pattern portion if (e.g., when) viewed on a plane.

According to one or more embodiments, the second pattern portions may include a (2-1)th pattern portion in which a length of one side is equal (e.g., substantially equal) to a length of an adjacent other side if (e.g., when) viewed on a plane.

According to one or more embodiments, the second pattern portions may include a (2-2)th pattern portion in which a length of one side is different from a length of an adjacent other side if (e.g., when) viewed on a plane.

According to one or more embodiments, among the second pattern portions, an area of each of one or more of the second pattern portions on a plane may be different from an area of each of one or more of the remaining second pattern portions on a plane.

According to one or more embodiments, the first lower inorganic layer and the first upper inorganic layer may include a first inorganic insulating (e.g., electrically insulating) material, and the second lower inorganic layer and the second upper inorganic layer may include a second inorganic insulating (e.g., electrically insulating) material.

According to one or more embodiments, the first inorganic insulating (e.g., electrically insulating) material may be silicon oxide, and the second inorganic insulating (e.g., electrically insulating) material may be silicon nitride.

According to one or more embodiments, in the forming or providing the second opening, the silicon substrate may be etched by wet etching.

According to one or more embodiments, the mask may be a deposition mask that is utilized to selectively deposit an organic material on a display substrate.

### BRIEF DESCRIPTION OF THE DRAWINGS

The accompanying drawings are included to provide a further understanding of embodiments of the subject matter of the present disclosure and are incorporated in and constitute a part of this specification. The drawings illustrate embodiments of the subject matter of the present disclosure, and, together with the description, serve to explain principles of embodiments of the subject matter of the present disclosure.

FIG. 1 is a plan view illustrating a mask according to one or more embodiments.

FIG. 2 is a plan view illustrating an enlarged view of one cell opening area as shown in FIG. 1.

FIG. 3 is a cross-sectional view taken along the line X1-X1′ in FIG. 2.

FIGS. 4-20 are diagrams illustrating a method for manufacturing a mask according to one or more embodiments.

FIGS. 21-25 are diagrams illustrating a method of manufacturing a mask according to one or more embodiments.

FIGS. 26-30 are diagrams illustrating a deposition process that utilizes a mask.

### DETAILED DESCRIPTION

Hereinafter, embodiments of the present disclosure will be described in more detail with reference to the accompanying drawings. It should be noted that in the following description, only parts necessary to understand the operation according to the present disclosure are described, and descriptions of other parts may not be provided in order not to obscure the subject matter of the present disclosure. In one or more embodiments, the present disclosure is not limited to the embodiments described herein and may be embodied in one or more suitable forms. However, the embodiments described herein are provided to explain in more detail so that those skilled in the art can easily practice the spirit and scope of the present disclosure.

The same reference numerals are used for substantially the same components or elements in the drawings, and redundant descriptions of substantially the same components or elements may not be provided.

Like reference numerals refer to like elements throughout. In one or more embodiments, in the drawings, the thicknesses, the ratios, and the dimensions of elements may be exaggerated for effective description of the technical contents. As used herein, the term “and/or” includes any and all combinations that the associated configurations or arrangements can define.

Throughout the specification, if (e.g., when) a first part is referred to as being connected or coupled to a second part, this includes not only a case where the first part and the second part are directly connected or coupled, but also a case where they are indirectly connected or coupled by another element between them. Terms used herein are for describing specific embodiments and are not intended to limit the present disclosure. Throughout the specification, if (e.g., when) a part includes a certain component, unless the context clearly indicates otherwise, this refers to that it may further include other components rather than excluding other components. At least one selected from among X, Y, and Z, and at least one selected from the group consisting of X, Y, and Z may be construed as one X, one Y, one Z, or any suitable combination of two or more of X, Y, and Z (for example, XYZ, XYY, YZ, and ZZ). As used herein, the term “and/or” may include any suitable combination of one or more of the corresponding elements.

Although the terms “first”, “second”, and/or the like may be used herein to describe one or more elements, these elements should not be limited by these terms. These terms are only used to distinguish one element from another element. Thus, a first element discussed in the present disclosure may be termed a second element without departing from the scope of the present disclosure.

Spatially relative terms, such as “beneath”, “below”, “under”, “lower”, “above”, “upper”, “over”, and/or the like may be used herein for descriptive purposes. By doing so, the relationship between one element or feature and another element(s) or feature(s) may be explained, as illustrated in the drawings. Spatially relative terms are intended to include other directions in use, operation, and/or manufacture, in addition to the directions depicted in the drawings. For example, if (e.g., when) the device as illustrated in the drawings is turned upside down, elements depicted as being “below” or “beneath” other elements or features are positioned “above” the other elements or features. Thus, in one or more embodiments, the term “below” may include both directions “above” and “below”. In one or more embodiments, the device may be oriented in other directions (for example, rotated 90 degrees or in other directions). In one or more embodiments, the spatially relative terms used herein may be interpreted accordingly.

In the present disclosure, it will be understood that if (e.g., when) an element (or a region, a layer, a portion, and/or the like) is referred to as being “on”, “connected to”, or “coupled to” another element, it may be directly on, directly connected to, or directly coupled to the other element, or intervening elements may be present between the elements. In contrast, if (e.g., when) an element is referred to as being “directly on” another element, there may be no intervening elements present.

It will be understood that the terms “include/including” and/or “has/have/having”, if (e.g., when) used in the present disclosure, specify the presence of stated features, integers, steps, acts, operations, elements, components, and/or groups thereof, but do not preclude the presence or addition of one or more other features, integers, steps, acts, operations, elements, components, and/or groups thereof. Also, the terms “comprise(s)/comprising,” “include(s)/including,” “have/has/having” or similar terms include or support the terms “consisting of” and “consisting essentially of,” indicating the presence of stated features, integers, steps, acts, operations, elements, and/or components, without or essentially without the presence of other features, integers, steps, acts, operations, elements, components, and/or groups thereof.

One or more embodiments are described with reference to the drawings that ideal embodiments are schematically illustrated. In one or more embodiments, it should be understood that their shapes may vary depending, for example, on tolerances and/or manufacturing techniques. Accordingly, one or more embodiments disclosed herein should not be construed as being limited to the specific shapes shown in the drawings. For example, it should be interpreted to include changes in shape that occur as a result of manufacturing. As such, the shapes shown in the drawings may not illustrate the actual shapes of areas of the device, and embodiments of the present disclosure are not be limited thereto.

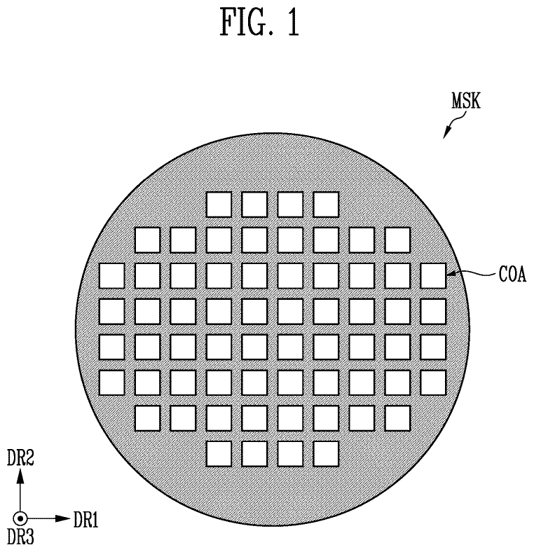

FIG. 1 is a plan view illustrating a mask according to one or more embodiments.

Referring to FIG. 1, cell opening areas COA may be provided within a mask MSK. Each of the cell opening areas COA may be an area that corresponds to one deposition target.

In each of the cell opening areas COA, the mask MSK may include openings. In one or more embodiments, after deposition targets are aligned to correspond to (or overlap) the cell opening areas COA, a deposition process may be performed to selectively deposit a deposition material on each of the deposition targets by utilizing the mask MSK.

In one or more embodiments, the cell opening areas COA may be arranged or provided to be spaced and/or apart (e.g., spaced apart or separated) from each other along a first direction DR1 and a second direction DR2 that is perpendicular (e.g., substantially perpendicular) to the first direction DR1. However, the arrangement of the cell opening areas COA is not limited thereto. The cell opening areas COA may be arranged or provided in one or more suitable forms.

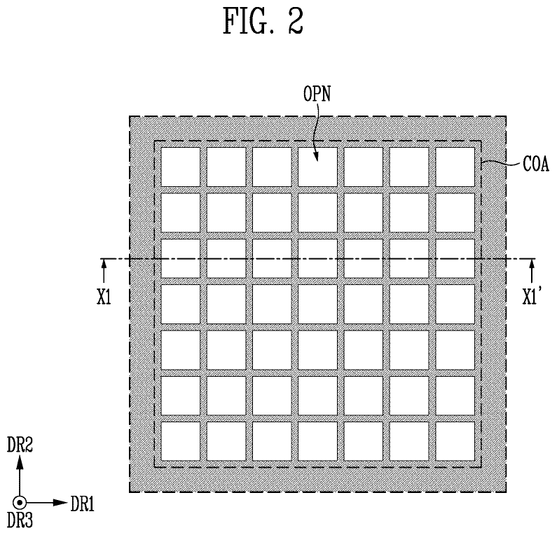

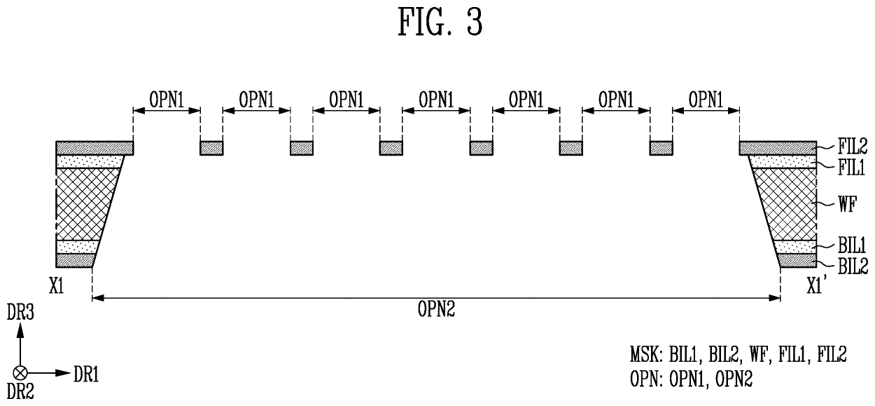

FIG. 2 is a plan view illustrating an enlarged view of one cell opening area as illustrated in FIG. 1. FIG. 3 is a cross-sectional view taken along the line X1-X1′ in FIG. 2.

Hereinafter, the description of one cell opening area COA with reference to FIGS. 2 and 3 may be substantially identically (or similarly) applied to each of the cell opening areas COA as illustrated in FIG. 1.

Referring to FIG. 2, the mask MSK may include openings OPN arranged or provided within the cell opening area COA. In one or more embodiments, the openings OPN may be arranged or provided in a matrix form along the first direction DR1 and the second direction DR2. For example, FIG. 2 illustrates 49 openings OPN arranged or provided in a 7×7 matrix form. However, the arrangement of the openings OPN and the number of the openings OPN are not limited thereto. The openings OPN may be arranged or provided in one or more suitable forms and may be provided with more than 49 openings OPN or less than 49 openings OPN.

Referring to FIG. 3, the mask MSK may include a silicon substrate WF, a first lower inorganic layer BIL1, a second lower inorganic layer BIL2, a first upper inorganic layer FIL1, and a second upper inorganic layer FIL2.

The silicon substrate WF may include silicon. The silicon substrate WF may include single crystal silicon. The first lower inorganic layer BIL1 may be under the silicon substrate WF. The second lower inorganic layer BIL2 may be under the first lower inorganic layer BIL1. The first upper inorganic layer FIL1 may be on the silicon substrate WF. The second upper inorganic layer FIL2 may be on the first upper inorganic layer FIL1. The first lower inorganic layer BIL1, the second lower inorganic layer BIL2, the first upper inorganic layer FIL1, and the second upper inorganic layer FIL2 may include an inorganic insulating (e.g., electrically insulating) material.

In one or more embodiments, the first lower inorganic layer BIL1 and the first upper inorganic layer FIL1 may include a first inorganic insulating (e.g., electrically insulating) material. The second lower inorganic layer BIL2 and the second upper inorganic layer FIL2 may include a second inorganic insulating (e.g., electrically insulating) material. The first inorganic insulating (e.g., electrically insulating) material may be a different type or kind of material from the second inorganic insulating (e.g., electrically insulating) material. For example, the first inorganic insulating (e.g., electrically insulating) material may be silicon oxide, and the second inorganic insulating (e.g., electrically insulating) material may be silicon nitride.

The second upper inorganic layer FIL2 may include first openings OPN1. The first openings OPN1 may correspond to the openings OPN as described with reference to FIG. 2. For example, the shape and arrangement of the first openings OPN1 on a plane may be substantially the same as the shape and arrangement of the openings OPN on a plane.

The first upper inorganic layer FIL1, the silicon substrate WF, the first lower inorganic layer BIL1, and the second lower inorganic layer BIL2 may include a second opening OPN2. The second opening OPN2 may be within the cell opening area COA. The second opening OPN2 may overlap the first openings OPN1. In one or more embodiments, the first openings OPN1 and the second opening OPN2 that overlap each other may be understood as defining the openings OPN.

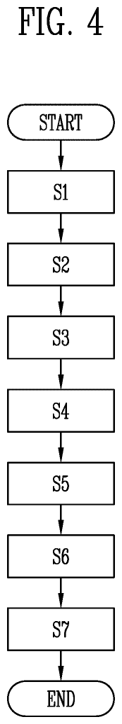

FIGS. 4 to 20 are diagrams illustrating a method for manufacturing a mask according to one or more embodiments.

Referring to FIG. 4, a method for manufacturing a mask may include a first step S1, a second step S2, a third step S3, a fourth step S4, a fifth step S5, a sixth step S6, and a seventh step S7.

The first step S1 and the second step S2 may be steps to form or provide a laminate. The third step S3, the fourth step S4, the fifth step S5, the sixth step S6, and the seventh step S7 may be steps to manufacture a mask that utilizes the laminate.

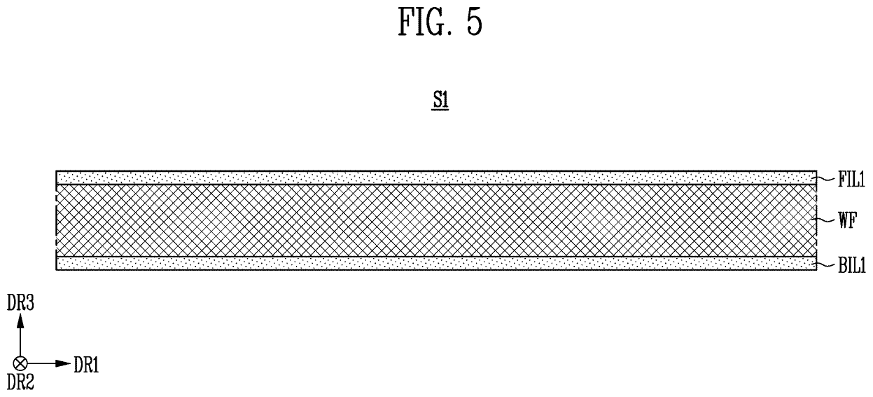

Referring to FIG. 5, a first lower inorganic layer BIL1 that covers a lower surface of a silicon substrate WF and a first upper inorganic layer FIL1 that covers an upper surface of the silicon substrate WF may be formed or provided (S1).

In one or more embodiments, the first lower inorganic layer BIL1 and the first upper inorganic layer FIL1 may include substantially the same material. For example, the first lower inorganic layer BIL1 and the first upper inorganic layer FIL1 may include silicon oxide.

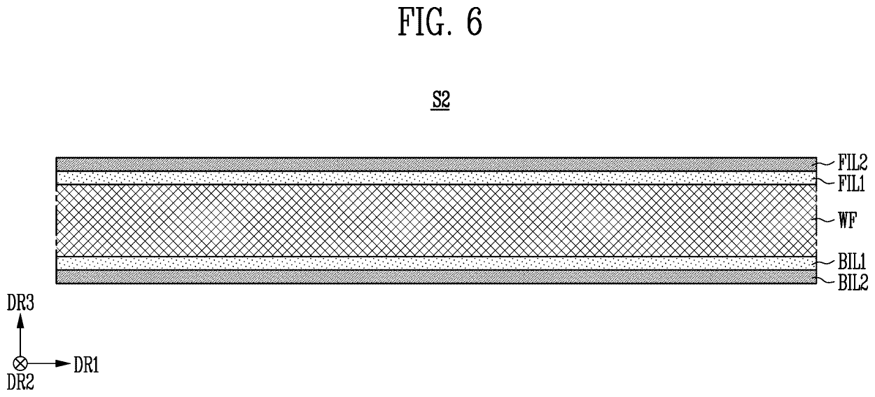

Referring to FIG. 6, a second lower inorganic layer BIL2 that covers a lower surface of the first lower inorganic layer BIL1 and a second upper inorganic layer FIL2 that covers an upper surface of the first upper inorganic layer FIL1 may be formed or provided (S2). In one or more embodiments, a laminate including the second lower inorganic layer BIL2, the first lower inorganic layer BIL1, the silicon substrate WF, the first upper inorganic layer FIL1, and the second upper inorganic layer FIL2 sequentially laminated along a third direction DR3 that is perpendicular (e.g., substantially perpendicular) to the first direction DR1 and the second direction DR2 may be formed or provided.

In one or more embodiments, the second lower inorganic layer BIL2 and the second upper inorganic layer FIL2 may include substantially the same material. For example, the second lower inorganic layer BIL2 and the second upper inorganic layer FIL2 may include silicon nitride.

Referring again to FIGS. 5 and 6, the order in which the components that constitute the laminate are formed or provided may be varied. For example, the first upper inorganic layer FIL1 and the second upper inorganic layer FIL2 may be formed or provided on the silicon substrate WF, and then the first lower inorganic layer BIL1 and the second lower inorganic layer BIL2 may be formed or provided under the silicon substrate WF.

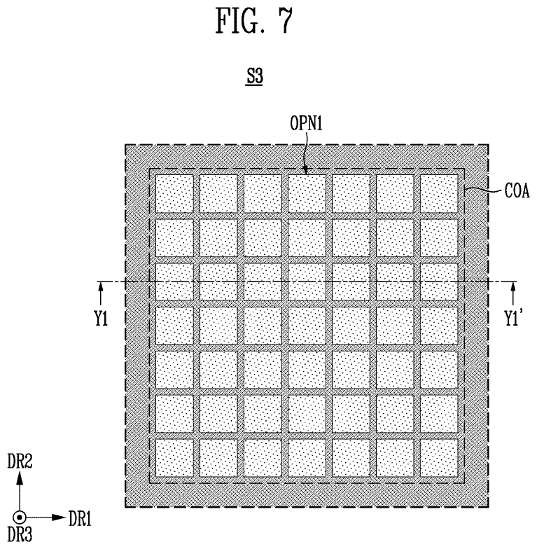

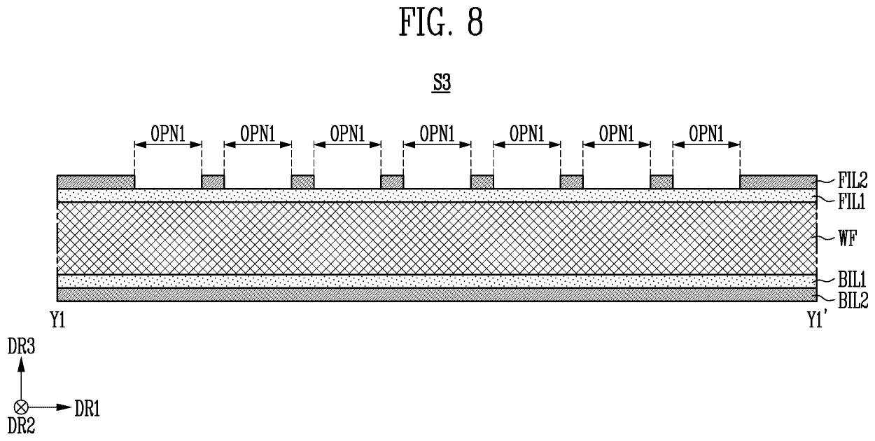

Referring to FIGS. 7 and 8, within the cell opening area COA, first openings OPN1 may be formed or provided to penetrate the second upper inorganic layer BIL2 and expose the upper surface of the first upper inorganic layer BIL1 (S3). The first openings OPN1 may be formed or provided to have a shape and/or an arrangement that corresponds to the openings OPN as described with reference to FIG. 2.

In this step (S3), the second upper inorganic layer BIL2 may be patterned to form or provide the first openings OPN1. The patterning of the second upper inorganic layer BIL2 may be performed, for example, by a dry etching method.

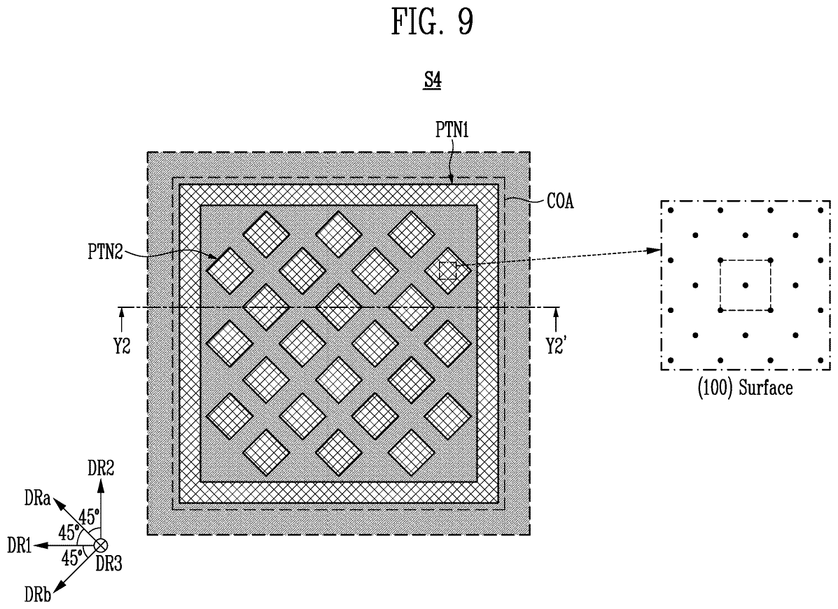

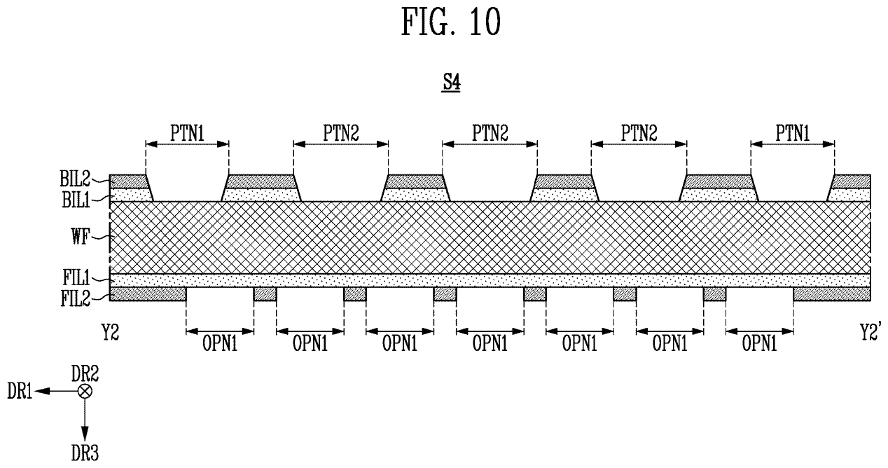

Referring to FIGS. 9 and 10, within the cell opening area COA, a first pattern portion PTN1 and second pattern portions PTN2 may be formed or provided to penetrate the first lower inorganic layer BIL1 and the second lower inorganic layer BIL2 and expose the lower surface of the silicon substrate WF (S4).

In this step (S4), etching may be performed in a direction of a back surface (or lower surface) of the laminate to form or provide the first pattern portion PTN1 and the second pattern portions PTN2. This etching may be, for example, dry etching. In FIG. 9, the back surface (or lower surface) of the laminate is illustrated.

The silicon substrate WF may include single crystal silicon. In one or more embodiments, the lower surface of the silicon substrate WF may be a (100) plane. FIG. 9 schematically illustrates the crystal structure of the lower surface of the silicon substrate WF which is a (100) plane.

If (e.g., when) viewed on a plane, the first pattern portion PTN1 may have a closed loop shape. If (e.g., when) viewed on a plane, each of sides that constitutes the first pattern portion PTN1 may be parallel (e.g., substantially parallel) to a [010] direction or a [001] direction. In one or more embodiments, the [010] direction may correspond to the second direction DR2 based on the (100) plane as illustrated in FIG. 9, and the [001] direction may correspond to the first direction DR1 based on the (100) plane as illustrated in FIG. 9.

For example, if (e.g., when) viewed on a plane, the first pattern portion PTN1 may include an outer edge and an inner edge. An area between the outer edge and the inner edge of the first pattern portion PTN1 may be an area where the lower surface of the silicon substrate WF is exposed. Each of the outer edge and the inner edge of the first pattern portion PTN1 may have a rectangular shape (e.g., a substantially rectangular shape) with sides parallel (e.g., substantially parallel) to the first direction DR1 or the second direction DR2.

If (e.g., when) viewed on a plane, the second pattern portions PTN2 may be surrounded by the first pattern portion PTN1. For example, the second pattern portions PTN2 may be within an area surrounded by the inner edge of the first pattern portion PTN1.

If (e.g., when) viewed on a plane, each of sides that constitutes the second pattern portions PTN2 may be parallel (e.g., substantially parallel) to a [011] direction or a [011] direction. In one or more embodiments, the [011] direction may correspond to a first intermediate direction DRa that is a direction between the first direction DR1 and the second direction DR2 based on the (100) plane as illustrated in FIG. 9 and whose angles formed with the first direction DR1 and the second direction DR2 are 45 degrees. The [011] direction may correspond to a second intermediate direction DRb that is perpendicular (e.g., substantially perpendicular) to the first intermediate direction DRa and the third direction DR3 based on the (100) plane as illustrated in FIG. 9.

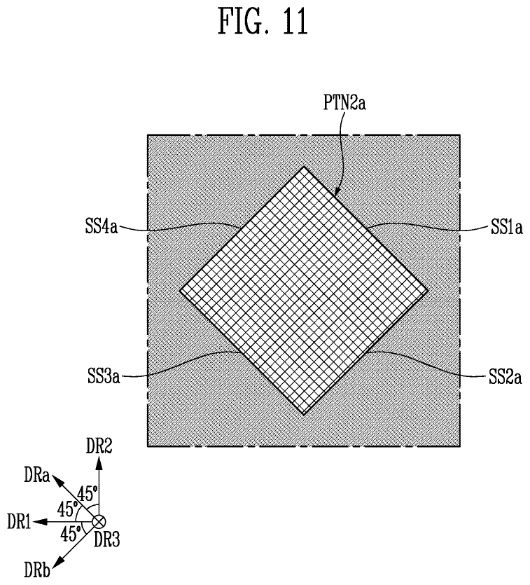

Each of the second pattern portions PTN2 may be implemented in any one selected from among the one or more shapes as illustrated in FIGS. 11 to 13.

Referring to FIG. 11, a (2-1)th pattern portion PTN2a is illustrated. The (2-1)th pattern portion PTN2a may include a first side SS1a, a second side SS2a, a third side SS3a, and a fourth side SS4a. The first side SS1a and the third side SS3a may be sides parallel (e.g., substantially parallel) to the first intermediate direction DRa, and the second side SS2a and the fourth side SS4a may be sides parallel (e.g., substantially parallel) to the second intermediate direction DRb. The lengths of the first side SS1a, the second side SS2a, the third side SS3a, and the fourth side SS4a may be substantially the same.

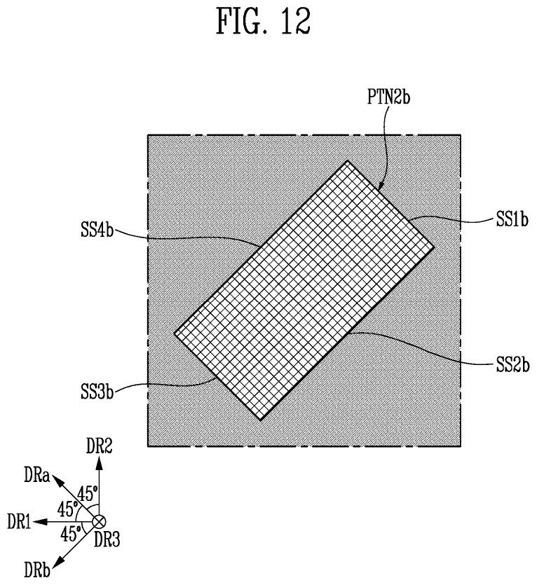

Referring to FIG. 12, a (2-2)th pattern portion PTN2b according to one or more embodiments is illustrated. The (2-2)th pattern portion PTN2b may include a first side SS1b, a second side SS2b, a third side SS3b, and a fourth side SS4b. The first side SS1b and the third side SS3b may be sides parallel (e.g., substantially parallel) to the first intermediate direction DRa, and the second side SS2b and the fourth side SS4b may be sides parallel (e.g., substantially parallel) to the second intermediate direction DRb. The length of each of the second side SS2b and the fourth side SS4b may be greater than the length of each of the first side SS1b and the third side SS3b.

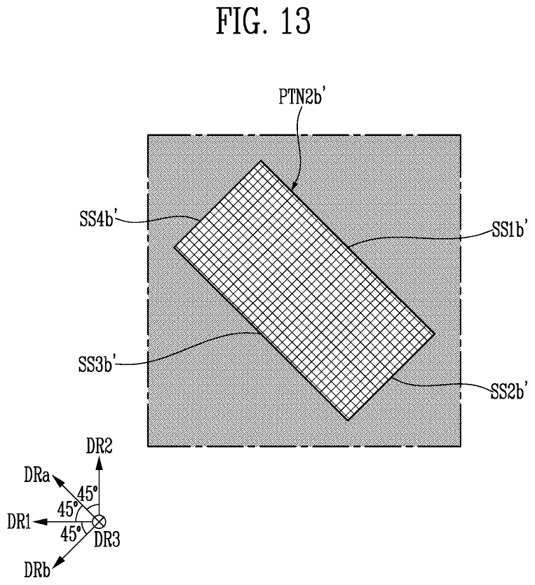

Referring to FIG. 13, a (2-2)th pattern portion PTN2b′ according to one or more embodiments is illustrated. The (2-2)th pattern portion PTN2b′ may include a first side SS1b′, a second side SS2b′, a third side SS3b′, and a fourth side SS4b′. The first side SS1b′ and the third side SS3b′ may be sides parallel (e.g., substantially parallel) to the first intermediate direction DRa, and the second side SS2b′ and the fourth side SS4b′ may be sides parallel (e.g., substantially parallel) to the second intermediate direction DRb. The length of each of the first side SS1b′ and the third side SS3b′ may be greater than the length of each of the second side SS2b′ and the fourth side SS4b′.

The second pattern portions PTN2 may be implemented with one or more suitable combinations of pattern portions having one or more shapes as described with reference to FIGS. 11 to 13.

For example, referring to FIG. 9, each of the second pattern portions PTN2 may be implemented as the (2-1)th pattern portion PTN2a as described with reference to FIG. 11. In one or more embodiments, areas of the second pattern portions PTN2 on a plane may be substantially the same.

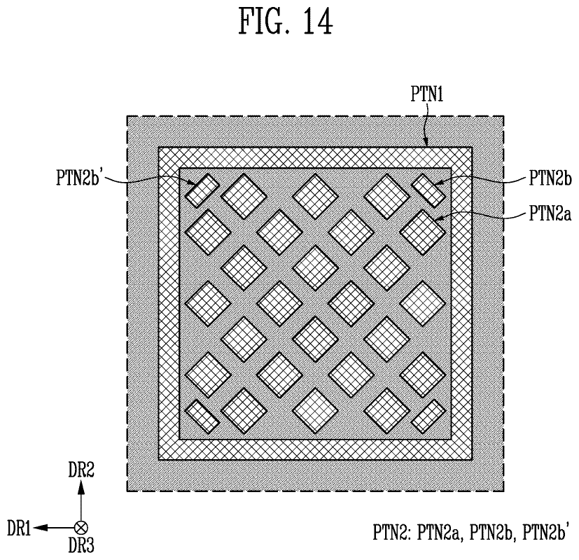

For another example, referring to FIG. 14, the second pattern portions PTN2 may be implemented by a combination of the (2-1)th pattern portion PTN2a as described with reference to FIG. 11, the (2-2)th pattern portion PTN2b as described with reference to FIG. 12, and the (2-2)th pattern portion PTN2b′ as described with reference to FIG. 13.

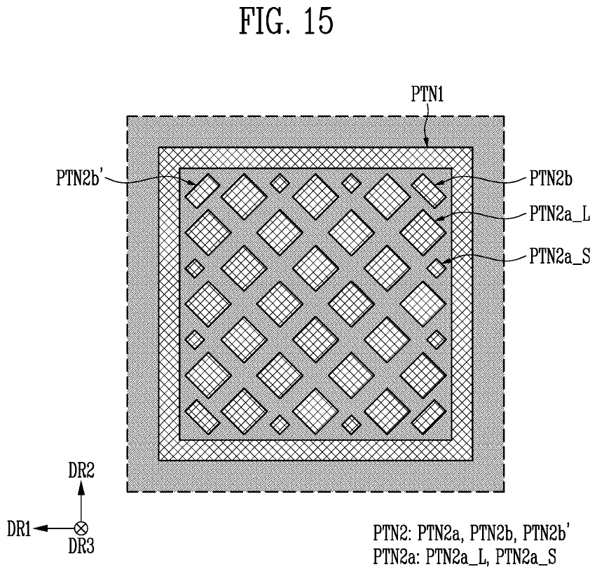

For another example, referring to FIG. 15, the second pattern portions PTN2 may be implemented by a combination of the (2-1)th pattern portion PTN2a as described with reference to FIG. 11, the (2-2)th pattern portion PTN2b as described with reference to FIG. 12, and the (2-2)th pattern portion PTN2b′ as described with reference to FIG. 13. In one or more embodiments, the (2-1)th pattern portion PTN2a may include a pattern portion PTN2a_L having a relatively large area on a plane and a pattern portion PTN2a_S having a relatively small area on a plane.

As described with reference to FIGS. 9 and 11 to 15, the second pattern portions PTN2 may be implemented with one or more suitable combinations of pattern portions having one or more areas on a plane, one or more arrangements on a plane, and one or more shapes on a plane, as long as each of the sides that constitutes the second pattern portions PTN2 is parallel (e.g., substantially parallel) to the [011] direction or the [011] direction.

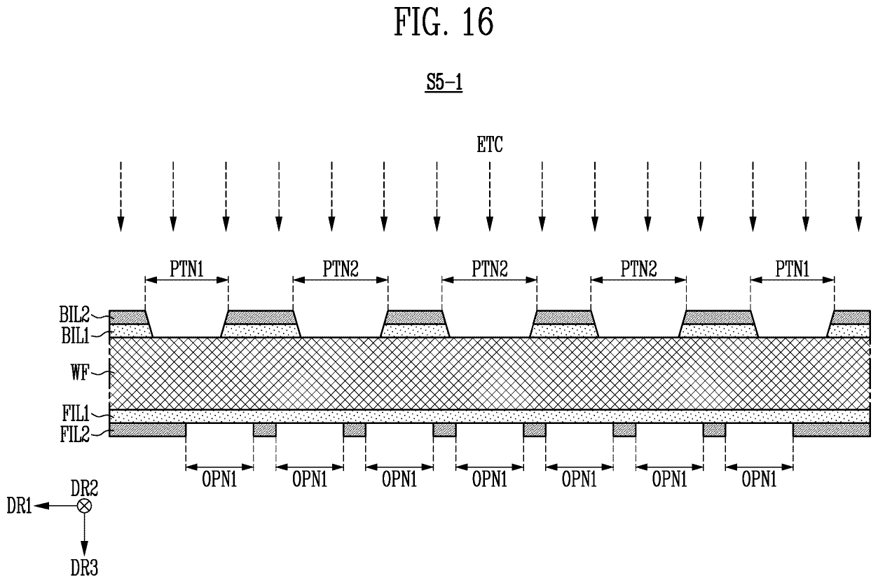

Referring to FIGS. 16 to 18, the silicon substrate WF may be etched through the first pattern portion PTN1 and the second pattern portions PTN2 to form or provide a second opening OPN2 that overlaps the first openings OPN1 (S5). For example, this step (S5) may include a (5-1)th step (S5-1), a (5-2)th step (S5-2), and a (5-3)th step (S5-3).

Referring to FIG. 16, a wet etching process may be initiated in which an etchant ETC is sprayed toward the lower surface of the silicon substrate WF (S5-1). The etchant ETC may contact the lower surface of the silicon substrate WF exposed by the first pattern portion PTN1 and the second pattern portions PTN2.

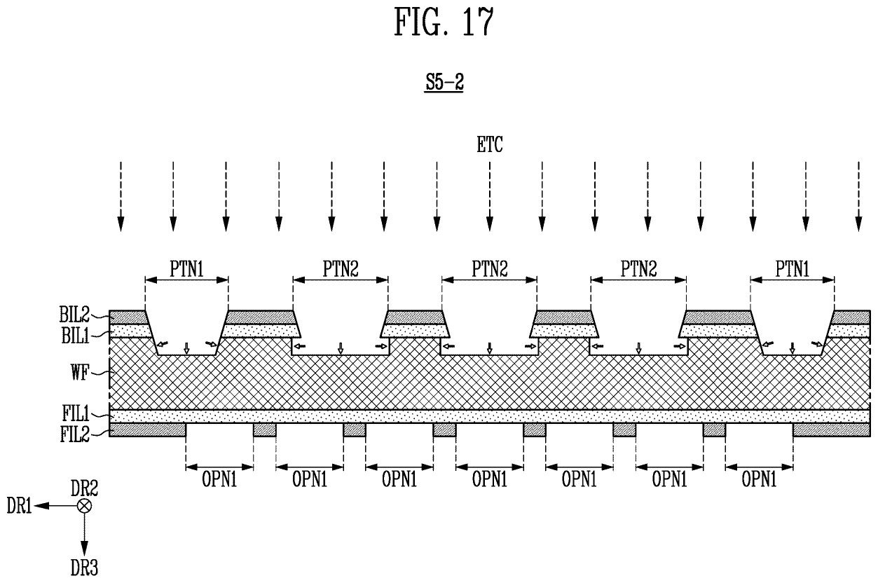

Referring to FIG. 17, the silicon substrate WF may be etched by the etchant ETC (S5-2). In one or more embodiments, because the lower surface of the silicon substrate WF is provided as the (100) plane, and the first pattern portion PTN1 and the second pattern portions PTN2 have the shapes on a plane as described with reference to FIGS. 9 to 15, the etching of the silicon substrate WF may be performed in a set or specific direction (or shape).

For example, as illustrated in FIG. 17, the etching of the silicon substrate WF exposed by the first pattern portion PTN1 may be performed so as to have a cross-sectional shape of an inverted trapezoid (a substantially inverted trapezoid). For example, as illustrated in FIG. 17, the etching of the silicon substrate WF exposed by the second pattern portions PTN2 may be performed so as to have a cross-sectional shape of a rectangle (e.g., a substantially rectangle).

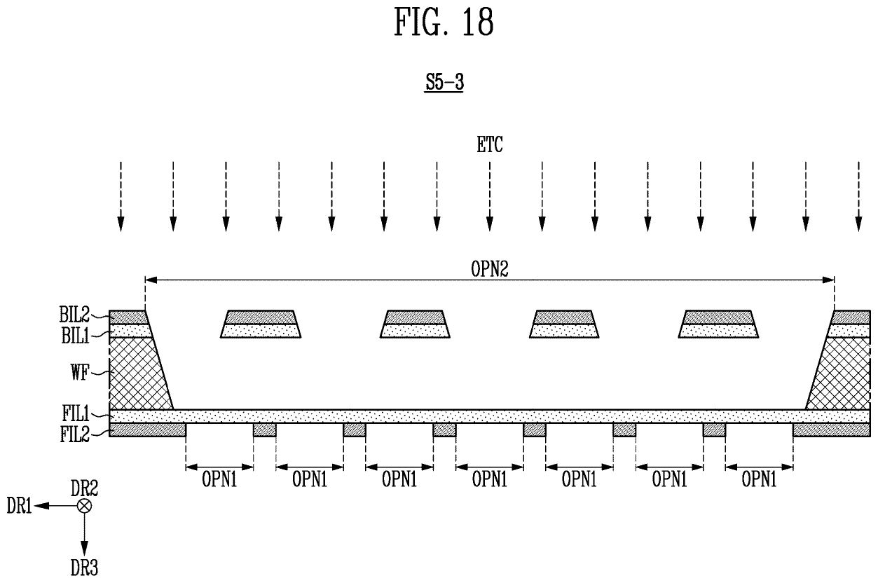

Referring to FIG. 18, after sufficient or suitable etching time has elapsed, the etching of the silicon substrate WF may be completed, thereby forming or providing the second opening OPN2 (S5-3).

Referring again to FIGS. 16 to 18, the second opening OPN2 may be formed or provided more effectively or suitably as the silicon substrate WF is etched in a set or specific direction (or shape) due to the crystal direction of the silicon substrate WF, the shape of the first pattern portion PTN1 on a plane considering the crystal direction, and the shapes of the second pattern portions PTN2 on a plane considering the crystal direction. For example, in an area where the second opening OPN2 is formed or provided, the silicon substrate WF may be etched relatively uniformly through the pattern portions PTN1 and PTN2. In one or more embodiments, if (e.g., when) the etching is completed (S5-3), there may be substantially no residue of the silicon substrate WF on the lower surface of the first upper inorganic layer FIL1.

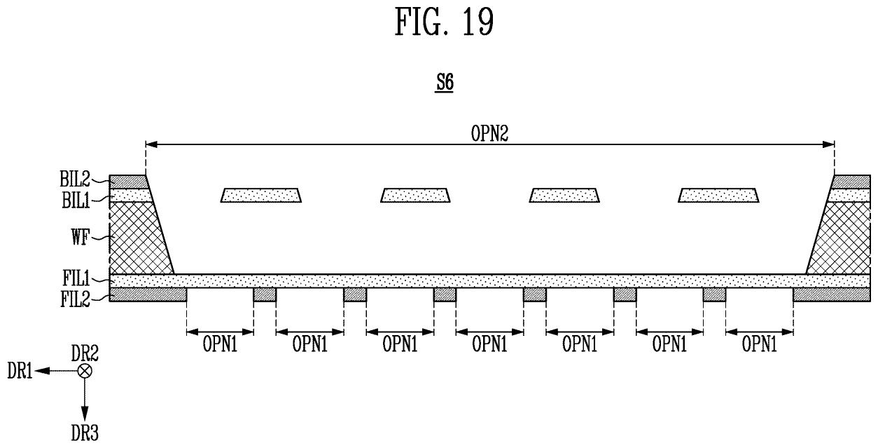

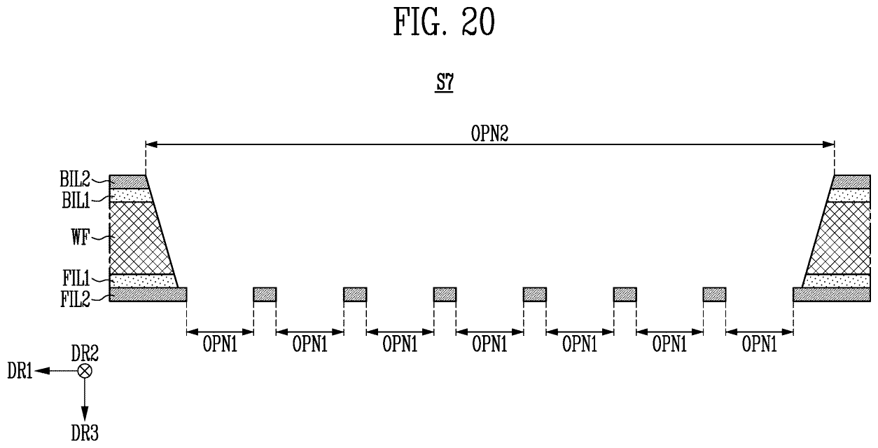

Referring to FIGS. 19 and 20, the first lower inorganic layer BIL1, the second lower inorganic layer BIL2, and the first upper inorganic layer FIL1 that overlap the second opening OPN2 may be removed (S6 and S7).

First, referring to FIG. 19, the second lower inorganic layer BIL2 that overlaps the second opening OPN2 may be removed (S6). The second upper inorganic layer FIL2 and the second lower inorganic layer BIL2 may include different materials from the first lower inorganic layer BIL1 and the first upper inorganic layer FIL1. For example, the second upper inorganic layer FIL2 and the second lower inorganic layer BIL2 may include silicon nitride, and the first lower inorganic layer BIL1 and the first upper inorganic layer FIL1 may include silicon oxide. In one or more embodiments, in this step (S6), the second lower inorganic layer BIL2 having an etching ratio different from that of the first lower inorganic layer BIL1 and the first upper inorganic layer FIL1 may be selectively etched and removed.

Thereafter, referring to FIG. 20, the first lower inorganic layer BIL1 and the first upper inorganic layer FIL1 that overlap the second opening OPN2 may be removed (S7). In this step (S7), the first lower inorganic layer BIL1 and the first upper inorganic layer FIL1 having different etching ratios than the second lower inorganic layer BIL2 and the second upper inorganic layer FIL2 may be selectively etched and removed. In one or more embodiments, in this step (S7), the second upper inorganic layer FIL2 including the first openings OPN1 may not be substantially removed by etching. For example, the reliability of the first openings OPN1 may be ensured.

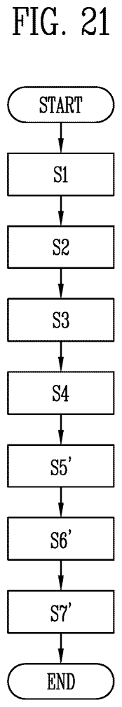

FIGS. 21 to 25 are diagrams illustrating a method of manufacturing a mask according to one or more embodiments.

Referring to FIG. 21, a method for manufacturing a mask may include a first step S1, a second step S2, a third step S3, a fourth step S4, a fifth step S5′, a sixth step S6′, and a seventh step S7′.

In one or more embodiments, the first step S1, the second step S2, the third step S3, and the fourth step S4 may be substantially the same as the steps as described with reference to FIGS. 6 to 15. Therefore, description of the overlapping content will not be provided.

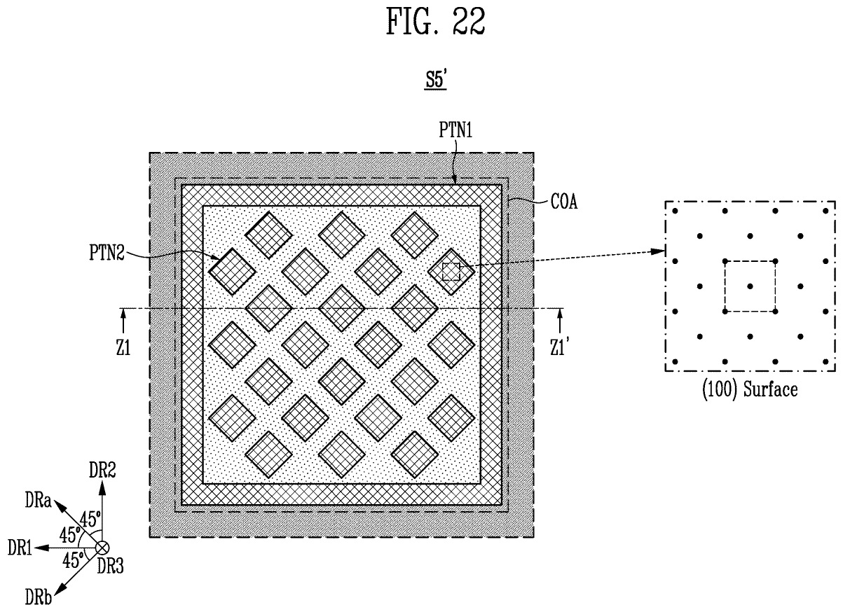

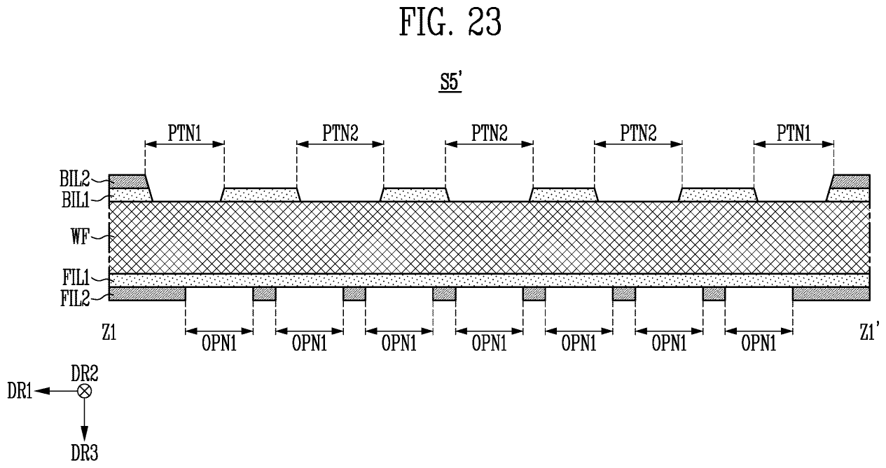

Referring to FIGS. 22 and 23, in an area that overlaps with an area surrounded by the first pattern portion PTN1 if (e.g., when) viewed on a plane, the second lower inorganic layer BIL2 may be removed (S5′). In this step (S5′), the first lower inorganic layer BIL1 may not be substantially removed. In one or more embodiments, the first pattern portion PTN1 and the second pattern portions PTN2 that expose the lower surface of the silicon substrate WF may be maintained.

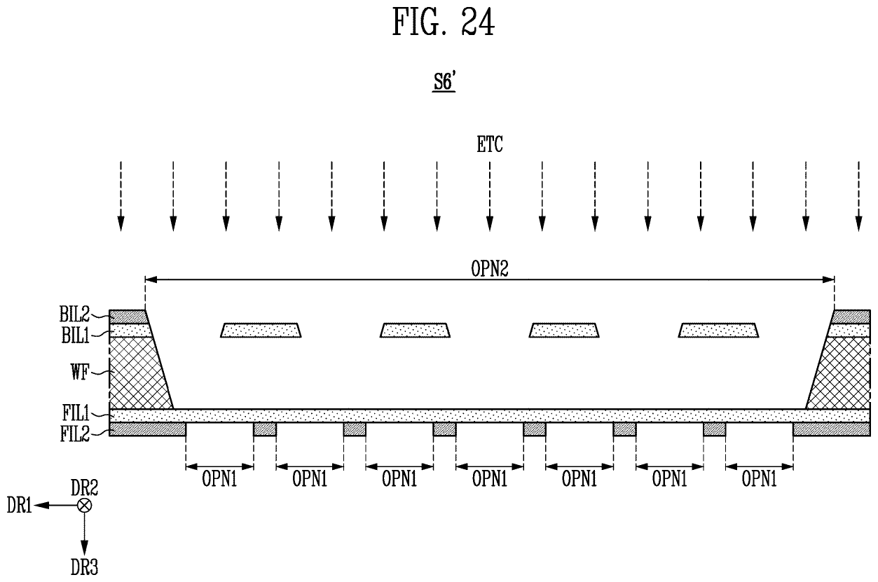

Referring to FIG. 24, the silicon substrate WF may be etched through the first pattern portion PTN1 and the second pattern portions PTN2 to form or provide the second opening OPN2 that overlaps the first openings OPN1 (S6′). This step (S6′) may be described substantially the same as the step (S5: S5-1, S5-2, and S5-3) as described with reference to FIGS. 16 to 18. Therefore, description of the overlapping content will not be provided.

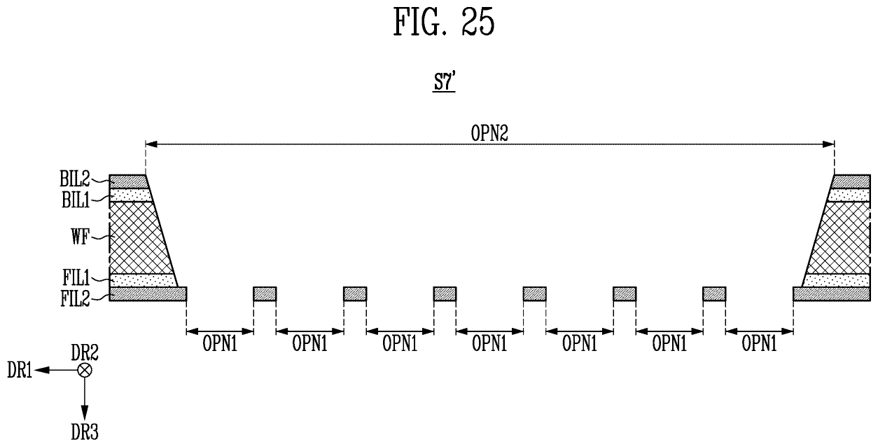

Referring to FIG. 25, the first lower inorganic layer BIL1 and the first upper inorganic layer FIL1 that overlap the second opening OPN2 may be removed (S7′). This step (S7′) may be described substantially the same as the step (S7) as described with reference to FIG. 20. Therefore, description of the overlapping content will not be provided.

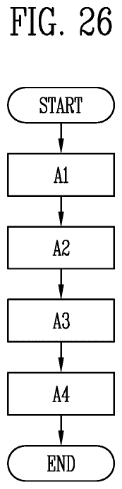

FIGS. 26 to 30 are diagrams illustrating a deposition process that utilizes a mask.

Referring to FIG. 26, a deposition process that utilizes a mask MSK may include a first step A1, a second step A2, a third step A3, and a fourth step A4.

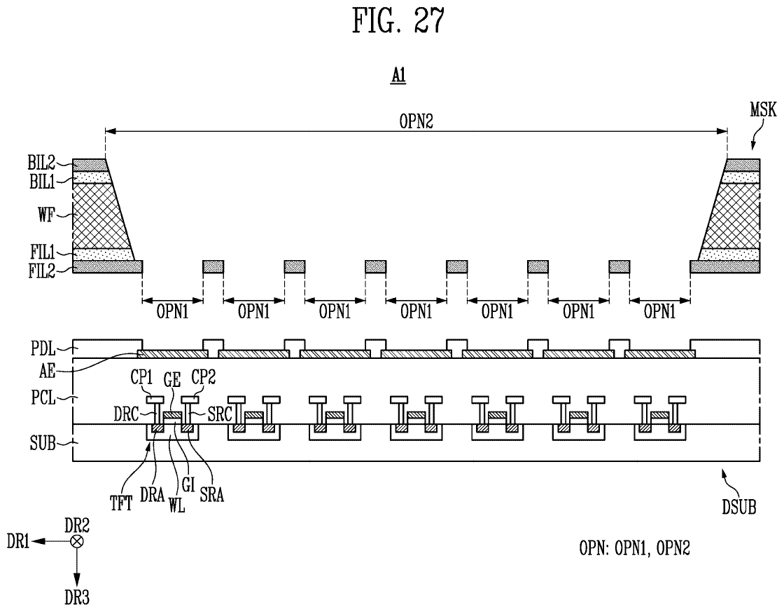

Referring to FIG. 27, the mask MSK may be provided on a display substrate DSUB, which is a deposition target (A1).

The display substrate DSUB may include a substrate SUB, a pixel circuit layer PCL, pixel electrodes AE, and a pixel defining layer PDL.

The substrate SUB may include a silicon wafer substrate formed or provided through a semiconductor process. For example, the substrate SUB may include silicon, germanium, and/or silicon-germanium.

The pixel circuit layer PCL may be on one surface of the substrate SUB. The substrate SUB and the pixel circuit layer PCL may include circuit elements. For example, the substrate SUB and the pixel circuit layer PCL may include a transistor TFT. A plurality of transistors TFT may be provided in the substrate SUB and the pixel circuit layer PCL.

The transistor TFT may include a source region SRA, a drain region DRA, and a gate electrode GE.

The source region SRA and the drain region DRA may be within the substrate SUB. A well WL formed or provided through an ion implantation process may be disposed or provided within the substrate SUB, and the source region SRA and the drain region DRA may be disposed or provided to be spaced and/or apart (e.g., spaced apart or separated) from each other within the well WL. A region between the source region SRA and the drain region DRA within the well WL may be defined as a channel region. The gate electrode GE may overlap the channel region between the source region SRA and the drain region DRA and may be in the pixel circuit layer PCL. The gate electrode GE may be separated from the well WL or the channel region by an insulating (e.g., electrically insulating) material, such as a gate insulating layer GI. The gate electrode GE may include a conductive (e.g., electrically conductive) material.

A plurality of layers in the pixel circuit layer PCL may include insulating (e.g., electrically insulating) layers and conductive (e.g., electrically conductive) patterns between the insulating (e.g., electrically insulating) layers. The conductive (e.g., electrically conductive) patterns may include, for example, a first conductive pattern CP1 and a second conductive pattern CP2. The first conductive pattern CP1 may be electrically connected to the drain region DRA via a drain connection portion DRC that penetrates one or more insulating (e.g., electrically insulating) layers. The second conductive pattern CP2 may be electrically connected to the source region SRA via a source connection portion SRC that penetrates one or more insulating (e.g., electrically insulating) layers.

The pixel electrodes AE may be on one surface of the pixel circuit layer PCL. The pixel electrodes AE may be connected to the transistors TFT, respectively. In one or more embodiments, each of the pixel electrodes AE may be referred to as an anode electrode.

The pixel defining layer PDL may be on one surface of the pixel circuit layer PCL. The pixel defining layer PDL may include pixel openings that expose portions of the pixel electrodes AE. In one or more embodiments, the pixel defining layer PDL may be between adjacent pixel electrodes AE.

The mask MSK may be aligned so that the first openings OPN1 overlap the pixel electrodes AE.

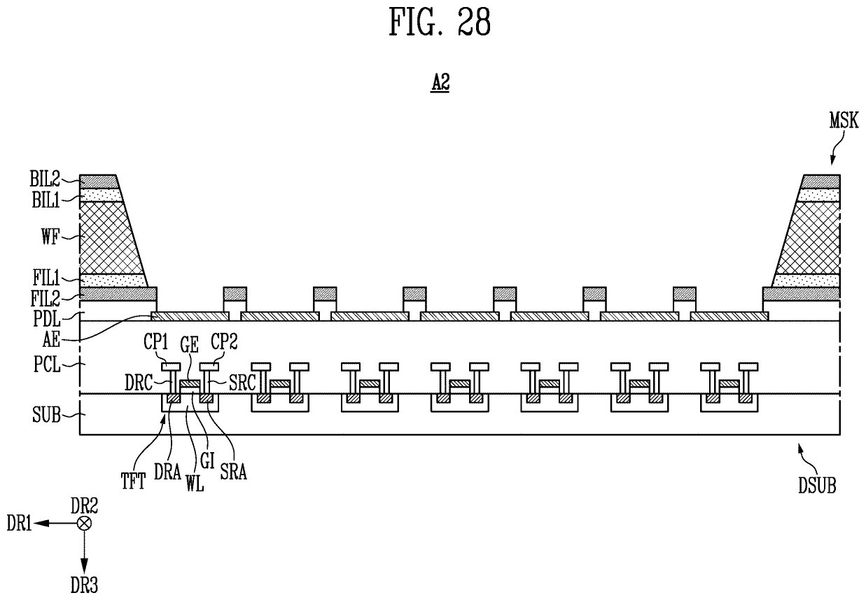

Referring to FIG. 28, the mask MSK may be moved relative to the display substrate DSUB so that the second upper inorganic layer FIL2 contacts the pixel defining layer PDL (A2). In this step (A2), the first openings OPN1 may overlap the pixel electrodes AE.

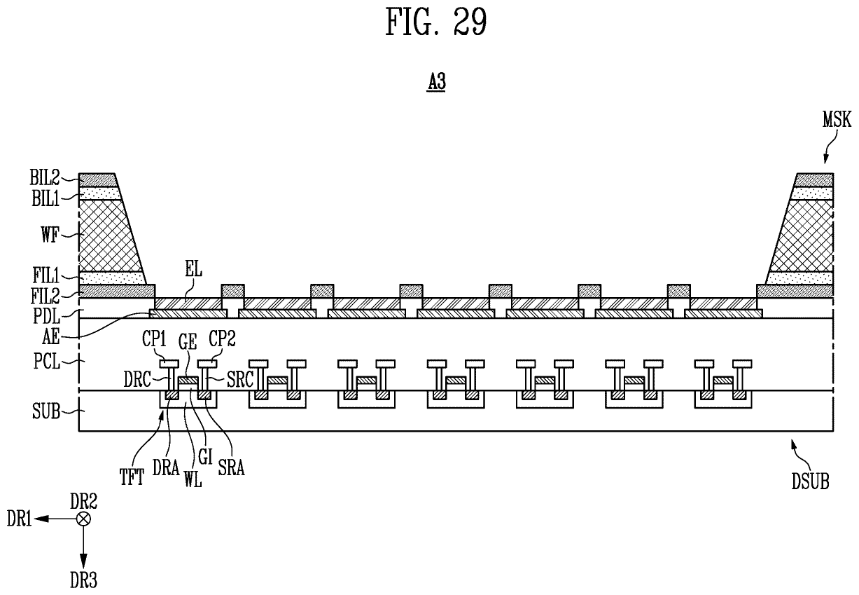

Referring to FIG. 29, by selectively providing a deposition material that utilizes the mask MSK, an organic light emitting material EL may be formed or provided on a pixel electrode AE within a pixel opening (A3).

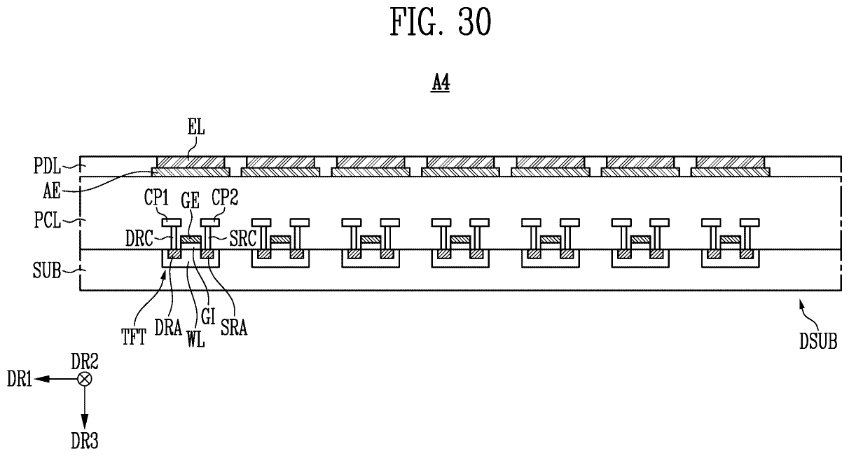

Referring to FIG. 30, the mask MSK may be removed (A4). Thereafter, steps of forming or providing components, such as a common electrode that faces the pixel electrode AE, may be further performed. In one or more embodiments, an electronic device including the display substrate DSUB may be provided.

According to the method for manufacturing the mask according to one or more embodiments of the present invention, a method for manufacturing a mask having improved or enhanced reliability may be provided by utilizing pattern portions that take into account the crystal direction of a silicon substrate if (e.g., when) manufacturing the mask.

Although one or more embodiments of the present disclosure have been described, it should be understood that the present disclosure should not be limited to these embodiments but one or more suitable changes and modifications can be made by one ordinary skilled in the art within the spirit and scope of the present disclosure as hereinafter claimed and equivalents thereof.

What is claimed is:

1. A method for manufacturing a mask that utilizes a laminate,
wherein the laminate comprises: a silicon substrate having a single crystal whose lower surface is a (100) plane; a first lower inorganic layer that covers the lower surface of the silicon substrate; a second lower inorganic layer that covers a lower surface of the first lower inorganic layer; a first upper inorganic layer that covers an upper surface of the silicon substrate; and a second upper inorganic layer that covers an upper surface of the first upper inorganic layer, and
wherein the method comprises:
providing first openings that penetrate the second upper inorganic layer within a cell opening area and expose the upper surface of the first upper inorganic layer;
providing a first pattern portion and second pattern portions within the cell opening area, wherein the first pattern portion penetrates the first lower inorganic layer and the second lower inorganic layer and exposes the lower surface of the silicon substrate, and wherein the second pattern portions are surrounded by the first pattern portion when viewed on a plane;
providing a second opening that overlaps the first openings by etching the silicon substrate through the first pattern portion and the second pattern portions; and
removing the first lower inorganic layer, the second lower inorganic layer, and the first upper inorganic layer that overlap the second opening,
wherein each of sides that constitutes the first pattern portion is substantially parallel to a [010] direction or a [001] direction when viewed on a plane, and
wherein each of sides that constitutes the second pattern portions is substantially parallel to a [011] direction or a [011] direction when viewed on a plane.

2. The method as claimed in claim 1, wherein the first pattern portion comprises an outer edge and an inner edge when viewed on a plane, and
wherein each of the outer edge and the inner edge has a rectangular shape.

3. The method as claimed in claim 2, wherein the second pattern portions are surrounded by the inner edge of the first pattern portion when viewed on a plane.

4. The method as claimed in claim 1, wherein the second pattern portions comprise a (2-1)th pattern portion in which a length of one side is equal to a length of an adjacent other side when viewed on a plane.

5. The method as claimed in claim 1, wherein the second pattern portions comprise a (2-2)th pattern portion in which a length of one side is different from a length of an adjacent other side when viewed on a plane.

6. The method as claimed in claim 1, wherein among the second pattern portions, an area of each of one or more of the second pattern portions on a plane is different from an area of each of one or more of the remaining second pattern portions on a plane.

7. The method as claimed in claim 1, wherein the first lower inorganic layer and the first upper inorganic layer comprise a first inorganic insulating material, and
wherein the second lower inorganic layer and the second upper inorganic layer comprise a second inorganic insulating material.

8. The method as claimed in claim 7, wherein the first inorganic insulating material is silicon oxide, and
wherein the second inorganic insulating material is silicon nitride.

9. The method as claimed in claim 1, wherein in the providing the second opening, the silicon substrate is etched by wet etching.

10. The method as claimed in claim 1, wherein the mask is a deposition mask that is utilized to selectively deposit an organic material on a display substrate.

11. A method for manufacturing a mask that utilizes a laminate,
wherein the laminate comprises: a silicon substrate having a single crystal whose lower surface is a (100) plane; a first lower inorganic layer that covers the lower surface of the silicon substrate; a second lower inorganic layer that covers a lower surface of the first lower inorganic layer; a first upper inorganic layer that covers an upper surface of the silicon substrate; and a second upper inorganic layer that covers an upper surface of the first upper inorganic layer, and
wherein the method comprises:
providing first openings that penetrate the second upper inorganic layer within a cell opening area and expose the upper surface of the first upper inorganic layer;
providing a first pattern portion and second pattern portions within the cell opening area, wherein the first pattern portion penetrates the first lower inorganic layer and the second lower inorganic layer and exposes the lower surface of the silicon substrate, and wherein the second pattern portions are surrounded by the first pattern portion when viewed on a plane;
removing the second lower inorganic layer that overlaps an area surrounded by the first pattern portion when viewed on a plane;
providing a second opening that overlaps the first opening by etching the silicon substrate through the first pattern portion and the second pattern portions; and
removing the first lower inorganic layer and the first upper inorganic layer that overlap the second opening,
wherein each of sides that constitutes the first pattern portion is substantially parallel to a [010] direction or a [001] direction when viewed on a plane, and
wherein each of sides that constitutes the second pattern portions is substantially parallel to a [011] direction or a [011] direction when viewed on a plane.

12. The method as claimed in claim 11, wherein the first pattern portion comprises an outer edge and an inner edge when viewed on a plane, and
wherein each of the outer edge and the inner edge has a rectangular shape.

13. The method as claimed in claim 12, wherein the second pattern portions are surrounded by the inner edge of the first pattern portion when viewed on a plane.

14. The method as claimed in claim 11, wherein the second pattern portions comprise a (2-1)th pattern portion in which a length of one side is equal to a length of an adjacent other side when viewed on a plane.

15. The method as claimed in claim 11, wherein the second pattern portions comprise a (2-2)th pattern portion in which a length of one side is different from a length of an adjacent other side when viewed on a plane.

16. The method as claimed in claim 11, wherein among the second pattern portions, an area of each of one or more of the second pattern portions on a plane is different from an area of each of one or more of the remaining second pattern portions on a plane.

17. The method as claimed in claim 11, wherein the first lower inorganic layer and the first upper inorganic layer comprise a first inorganic insulating material, and
wherein the second lower inorganic layer and the second upper inorganic layer comprise a second inorganic insulating material.

18. The method as claimed in claim 17, wherein the first inorganic insulating material is silicon oxide, and
wherein the second inorganic insulating material is silicon nitride.

19. The method as claimed in claim 11, wherein in the providing the second opening, the silicon substrate is etched by wet etching.

20. The method as claimed in claim 11, wherein the mask is a deposition mask that is utilized to selectively deposit an organic material on a display substrate.
